(19) United States
(12) Patent Application Publication
(10) Pub. No.: US 2015/0303364 A1
(43) Pub. Date: Oct. 22, 2015

(54) Thermoelectrical Generator

(71) Applicant: Laurier LIEVRE, Mundare (CA)

(72) Inventor: Laurier Lievre, Mundare (CA)

(21) Appl. No.: 14/435,083

(22) PCT Filed: Oct. 10, 2013
(86) PCT No.: PCT/CA2013/050766

§ 371 Date: Apr. 10, 2015

Related U.S. Application Data
(60) Provisional application No. 61/711,966, filed on Oct. 10, 2012.

(51) Int. Cl. H01L 35/32

(52) U.S. Cl. CPC H01L 35/32

(57) ABSTRACT

A thermoelectric generator device includes an inner wall, a support wall and an outer wall which are polygonal in cross sections and concentric with one another to define a generally annular chamber on either side of the support wall. Thermoelectric modules are mounted in the support wall in communication with inner and outer ones of the two chambers to generate electrical power when subjected to a temperature differential between the chambers. Heat transfer fluids are communicated between the chambers and respective ones of a first temperature source and a second temperature source which are different from one another. The annular arrangement permits multiple thermoelectric modules to communicate with the heat transfer fluids with greater efficiency than prior art arrangements in which the modules are alternately stacked.

### FIELD OF THE INVENTION

The present invention relates to a thermoelectric generator device for generating electrical power from a temperature differential between first and second heat sources, and more particularly the present invention relates to a structure for supporting a plurality of thermoelectric generator modules for communication with common first and second heat sources.

### BACKGROUND

A thermoelectric generator module is a commercially available device which generally comprises a first side, a second side opposite the first side, and a core of semi-conductive material arranged between the first and second sides which is arranged to generate electrical power when subjected to a temperature differential between the first and second sides.

US Patent application Publication 2009/0301541 by Watts discloses one example of thermoelectric generator modules arranged in a stacked configuration in alternating orientation such that heat transfer fluid from a hot source can be passed between adjacent first sides of the stacked modules and heat transfer fluid from a cold source can be passed between adjacent second sides of the stacked modules. The close proximity of the hot and cold heat transfer fluids in alternating configuration in the stack may result in a loss in temperature differential and reduced efficiency in the stacked configuration.

### SUMMARY OF THE INVENTION

According to one aspect of the invention there is provided a thermoelectric generator device for generating electrical power from a difference in temperature between a first source and a second source, the device comprising:

an inner wall which is generally annular about a central axis;

a support wall which is generally annular about the central axis so as to surround the inner wall at a location spaced radially outwardly from the inner wall to define an inner chamber which is annular in shape between the inner wall and the support wall;

an outer wall which is generally annular about the central axis so as to surround the support wall at a location spaced radially outwardly from the support wall to define an outer chamber which is annular in shape between the support wall and the outer wall;

a plurality of thermoelectric modules wherein:
each thermoelectric module comprises a first side, a second side, and a core between the first and second sides which is arranged to generate electrical power when subjected to a temperature differential between its respective first and second sides; and
each thermoelectric module is supported on the support wall such that the first side is in communication with the inner chamber and such that the second side is in communication with the outer chamber;

a first heat transfer fluid in communication between the inner chamber and the first source; and

a second heat transfer fluid in communication between the outer chamber and the second source.

The annular configuration permits the first sides of all of the thermoelectric modules to more readily commonly communicate with a heat transfer fluid from one source on one side of the support wall while the second sides of all of the thermoelectric modules also readily commonly communicate with a heat transfer fluid from a different source on the other side. This arrangement permits the first and second sides to be more insulated and isolated from one another to use the temperature differential between the first and second sources with greater efficiency than some prior art arrangements such as an alternating stacked configuration for example.

In the illustrated embodiment the support wall is polygonal so as to define a plurality of flat sides in series with one another in a circumferential direction about the central axis, each flat side supporting at least one thermoelectric module therein. In this instance, preferably the inner wall is also polygonal so as to define a plurality of flat sides in series with one another in a circumferential direction about the central axis, each flat side being parallel to a corresponding one of the flat sides of the support wall. Similarly, the outer wall is also preferably polygonal in this instance so as to define a plurality of flat sides in series with one another in a circumferential direction about the central axis, each flat side being parallel to a corresponding one of the flat sides of the support wall.

Furthermore, the support wall may be generally frustoconical in shape.

Preferably the support wall comprises heat insulating material and each module is supported in a respective aperture in the insulating material such that the module is in sealing engagement relative to the support wall about a perimeter of the thermoelectric module and such that the first side is in direct communication with the inner chamber and such that the second side is in direct communication with the outer chamber.

Preferably the inner wall and the outer wall also comprise heat insulating material.

A first heat transfer medium is preferably provided in the inner chamber including tubing extending therethrough which receives the first heat transfer fluid therethrough. The tubing may extend through the first heat transfer medium in a helical pattern about the central axis.

Similarly a second heat transfer medium is preferably provided in the outer chamber including tubing extending therethrough which receives the second heat transfer fluid therethrough. The tubing through the second heat transfer medium preferably also extends in a helical pattern about the central axis.

More particularly, the first heat transfer medium in the inner chamber may include tubing extending therethrough from an inlet which receives the first heat transfer fluid from the first source to an outlet which returns the first heat transfer fluid to the first source, and the second heat transfer medium in the outer chamber may include tubing extending therethrough from an inlet which receives the second heat transfer fluid from the second source to an outlet which returns the second heat transfer fluid to the second source.

In some embodiments, one or both of the heat transfer mediums comprises a liquid.

Alternatively, one or both of the heat transfer mediums comprises a conductive material, for example a metallic powder such as copper powder.

When one of the first and second sources comprises a hot source which is hotter than the other one of the first and second sources, preferably the tubing associated with the hot source extends upwardly through the respective heat transfer medium from the inlet to the outlet thereof.

When one of the first and second sources comprises a cold source which is colder than the other one of the first and second sources, preferably the tubing associated with the cold source extends downwardly through the respective heat transfer medium from the inlet to the outlet thereof.

The tubing associated with the hot side is preferably located in the respective heat transfer medium nearer to a bottom end than a top end of the thermoelectric modules.

The tubing associated with the cold side is preferably located in the respective heat transfer medium nearer to the top end than the bottom end of the thermoelectric modules.

When one of the first and second sides of each thermoelectric module comprises a hot side and the other one of the first and second sides of each thermoelectric module comprises a cold side arranged such that the core generates electrical power when the hot side is subjected to a temperature which is greater than the cold side, preferably each thermoelectric module is supported at an inclination from vertical such that the hot side faces partially downward and such that the cold side faces partially upward.

According to a second aspect of the present invention there is provided a thermoelectric generator device for generating electrical power from a difference in temperature between a hot source and a cold source which is colder than the hot source, the device comprising:

a first boundary wall which is insulated;

a support wall supported parallel and spaced apart from the first boundary wall so as to define a first chamber between the first boundary wall and the support wall;

a second boundary wall which is insulated and which is supported parallel and spaced apart from the support wall opposite from the first boundary wall so as to define a second chamber between the support wall and the second boundary wall;

a plurality of thermoelectric modules wherein:
each thermoelectric module comprises a hot side, a cold side, and a core between the hot and cold sides which is arranged to generate electrical power when the hot side subjected to a temperature which is greater than the cold side; and
each thermoelectric module is supported on the support wall such that the hot side is in communication with the first chamber and such that the cold side is in communication with the second chamber;

a first heat transfer fluid in communication between the hot source and the first chamber adjacent a bottom side thereof; and

a second heat transfer fluid in communication between the cold source and the second chamber adjacent a top side thereof;

the support wall supporting each thermoelectric module at an inclination from vertical such that the hot side faces partially downward and such that the cold side faces partially upward.

Supporting the modules at an inclination such that the hot sides face partially downwardly takes advantage of naturally occurring thermodynamic convection as the heat transfer fluid from the hot source is introduced at the bottom side of the upwardly inclined and downward facing hot sides of the modules and convects upwardly through first chamber along the boundary formed by the hot side of the modules. Similarly, introducing the heat transfer fluid at the top side of the upward facing cold sides of the modules provides the most cooling at the location of the second chamber where cooling is most required for optimal efficiency.

Some embodiments of the invention will now be described in conjunction with the accompanying drawings in which:

### BRIEF DESCRIPTION OF THE DRAWINGS

FIG. 1 is a perspective view of the thermoelectric generator device according to the present invention shown schematically connected to respective hot and cold sources of temperature;

FIG. 2 is a side elevational view of the thermoelectric generator device;

FIG. 3 is a sectional view of the thermoelectric generator device along the line 3-3 in FIG. 2;

FIG. 4 is a side elevational view of one of the flat sides of the support wall supporting a set of thermoelectric modules therein;

FIG. 5 is a schematic representation of the interconnection of the six sets of thermoelectric modules together with a controller for outputting an electrical current to charge a battery or other uses; and

FIG. 6 is a sectional view of the thermoelectric generator device along the line 6-6 in FIG. 3.

FIG. 7 is a schematic representation of an alternative embodiment of the connection of the thermoelectric generator device to the respective hot and cold sources of temperature.

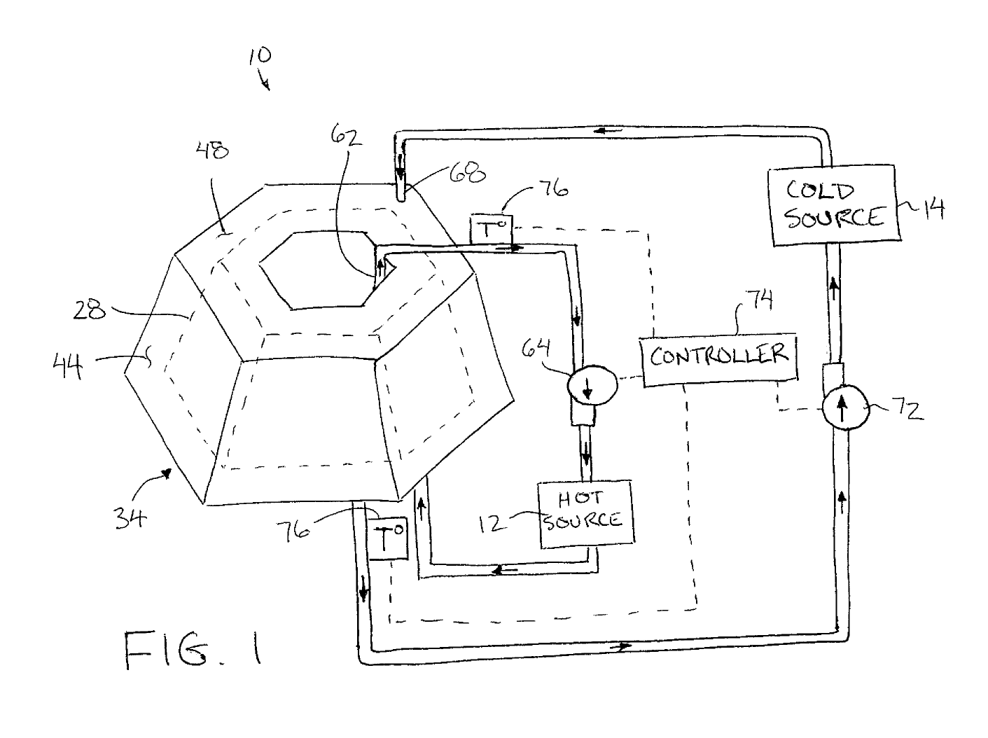

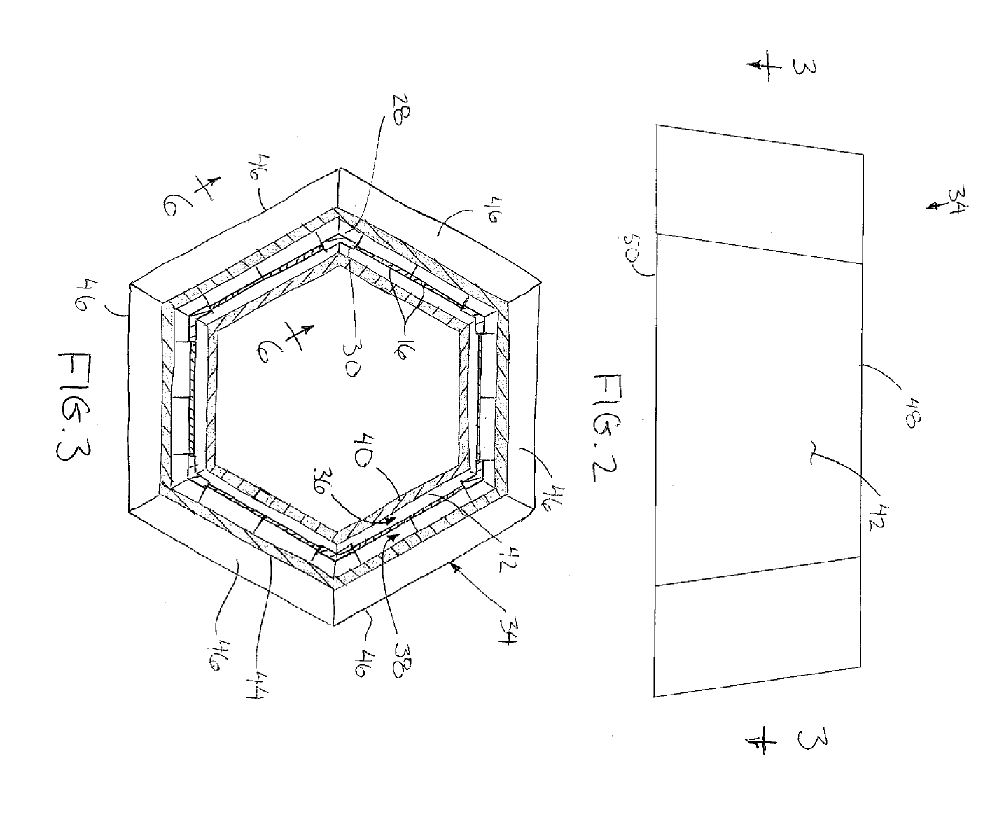

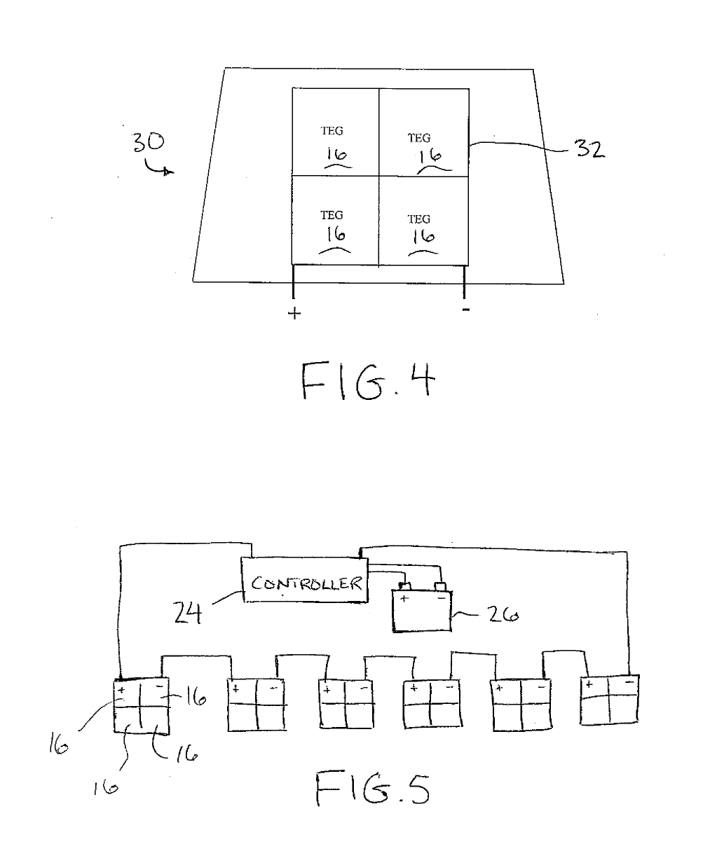

In the drawings like characters of reference indicate corresponding parts in the different figures.

### DETAILED DESCRIPTION

Referring to the accompanying figures there is illustrated a thermoelectric generator device 10 which is used with a first temperature source 12 and a second temperature source 14 for generating electrical power from a difference in temperature between the sources. In the illustrated embodiment the first source comprises a hot sink or other source of heat such as a solar water heater to provide a temperature source which is greater than a temperature of the second source which functions as a cold source and may take various forms of cold sinks.

The device 10 generally includes a plurality of thermoelectric generator modules 16 of the type which are generally commercially available as flat, rigid, thin rectangular panels. Typically the panels comprise a hot side layer 18 of conductive material spanning a first side of the panel, a cold side layer 20 of conductive material spanning an opposing second side of the panel opposite the first side, and a core layer 22 between the hot and cold layers. The core layer 22 comprises semi-conductive material arranged in a suitable configuration to generate an electrical current when the hot side is exposed to a temperature greater than the cold side by taking advantage of thermoelectric effects including the Seebeck effect and the Peltier effect.

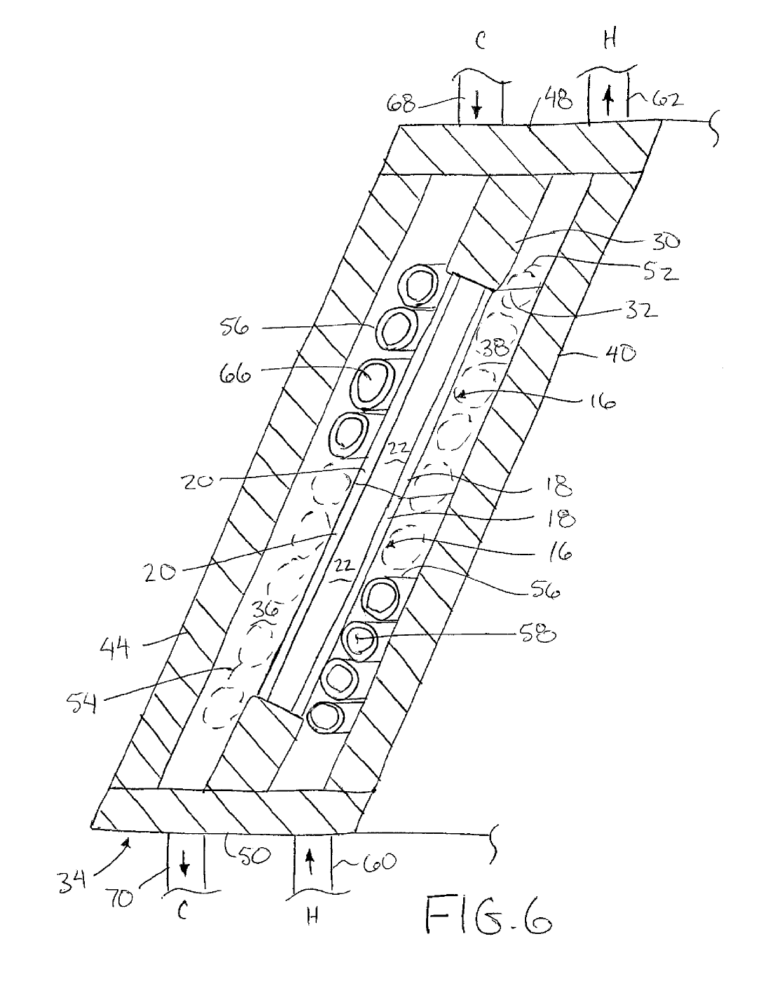

The device 10 supports the modules such that all of the hot sides commonly communicate with the hot source and all the cold sides communicate commonly with the cold source. The electrical output from the core layers of the modules are connected electrically in series with one another and with a suitable controller 24 as represented schematically in FIG. 5 for charging a battery 26 and for other uses as may be desired.

The structure of the device includes a support wall 28 which is generally annular about a central axis. The support wall is generally polygonal in cross section such that the support wall comprises a set of six flat sides 30 connected in series with one another in a circumferential direction about the central axis in which each flat side spans the full height between top and bottom ends of the device. Each of the flat sides is generally trapezoidal in shape so as to be narrower in the circumferential direction at the top end than the bottom end. The flat sides are joined to adjacent ones in series such that each flat side extends vertically upward at a radially inward inclination from the bottom end to the top end so that the top end is nearer to the central axis than the bottom end. The flat sides thus collectively define a generally frustoconical shape of the support wall. The support wall is generally formed of an insulating material for insulating between fluids communicated from the hot source on one side and fluids communication from the cold source on the other side.

In further embodiments, the cross sectional shape of the support wall can be any polygonal shape including a pentagon up to a dodecagon for example. A square would also work however there would be a large amount of wasted space when using such a small number of sides. The flat sides are generally configured in the manner described herein regardless of the number of sides. Furthermore, the overall size of the device can be scaled up or down so that each side of the support wall can support more or fewer modules 16 therein as may be desired.

Each side of the support wall comprises a central aperture 32 supporting a plurality of the modules 16 therein. In the illustrated embodiment four modules of generally square perimeter are mounted in a square pattern in a common plane such that abutted edges are in sealing engagement with one another. The set of modules is in turn closely fitted within a respective one of the central apertures 32 to fill the aperture by sealing engagement about the perimeter of the aperture. Each module is thus fully sealed about its perimeter edge either to an adjacent one of the modules or the support wall at the perimeter of the aperture 32 so that each module is effectively sealed about its full perimeter in relation to the surrounding support wall 28. All of the hot sides of the module are thus directly exposed to the space adjacent the inner surface of the support wall while all of the cold sides of the modules are directly exposed to the space adjacent the outer side of the support wall.

The device 10 further includes a tank structure 34 surrounding the support wall in which the support wall acts as a divider fully spanning between the top and bottom ends of the tank to separate the interior of the tank between an inner first chamber 36 adjacent the inner surface of the support wall and an outer second chamber 38 adjacent the outer side of the support wall. The tank is generally annular in shape about the central axis similar to the support wall such that both of the inner and outer chambers defined on opposing sides of the support wall are similarly generally annular about the central axis while being separated and prevented from communicating with one another by the support wall.

The tank 34 includes an inner wall 40 which is generally annular about the central axis so as to be concentric therewith while spanning the full height of the top and bottom ends of the device. The support wall 28 is positioned radially outward in relation to the inner wall so as to surround the inner wall and define the inner chamber as a radial gap between the inner wall and the support wall across the full height of the tank. The tank is generally polygonal in cross section similar to the support wall so as to comprise a similar number of six flat sides 42 which span the full height of the tank and which are connected in series with one another in the circumferential direction. The flat sides are also trapezoidal in shape so as to taper upwardly and inwardly at an inward inclination in the radial direction such that the flat sides 42 of the inner wall are parallel to corresponding ones of the flat sides of the support walls.

The outer wall is also generally annular in shape and concentric with the central axis, but is greater in radial dimension so as to fully surround the support wall spaced radially outward therefrom. The outer chamber is thus defined as the radial gap between the support wall and the outer wall which spans the full height of the tank.

The outer wall 44 is similarly generally polygonal in shape so as to comprise a plurality of similarly configured flat sides 46 connected in series in circumferential direction to span the full height of the tank. The flat sides are similarly trapezoidal in shape and inclined so as to be parallel to corresponding flat sides of the support wall.

To enclose the top and bottom ends of the tank there is provided a top wall 48 and a bottom wall 50. The top wall 48 spans generally radially in a horizontal orientation between the top edge of the inner wall and the top edge of the outer wall across the top edge of the support adjoined thereto. Similarly the bottom wall 50 spans radially in a horizontal orientation between the bottom edge of the inner wall and the bottom edge of the outer wall about the full perimeter thereof while being joined to the bottom edge of the support wall between the inner and outer edges.

In the illustrated embodiment, all of the walls of the tank are fully insulated to fully surround and enclose the inner and outer chambers respectively. A first heat transfer medium 52 is located in the inner chamber while a second heat transfer medium 54 is located within the outer chamber. The heat transfer mediums may comprise solid conductive material, for example a metallic powder such as copper, for evenly conveying heat across the entirety of the respective chambers. Alternatively, the heat transfer mediums may each comprise a heat transfer liquid so that heat can be evenly distributed throughout the chambers by convection. Typically the same heat transfer medium is provided within both chambers however the support wall ensures that the chambers are fully insulated and do not communicate relative to one another so that separate mediums can be used without cross contamination.

Both the inner chamber and outer chamber include heat transfer tubing 56 extending through the heat transfer medium within the chamber for communication between the chamber and a respective one of the first and second sources of temperature. The tubing is provided in a closed loop between the respective chamber and the respective source to convey heat transfer fluid circulated therethrough such that the heat transfer fluid is in a heat exchanging relationship with the medium located within the respective chamber while being prevented from directly communicating.

Within the inner chamber the heat transfer tubing 56 includes a first heat transfer fluid 58 which is circulated in a closed loop between the hot source 12 and the inner chamber. The tubing within the inner chamber extends helically upward from an inlet 60 at the bottom end to an outlet 62 spaced upwardly from the bottom end of the chamber part way towards the top end. In this instance a majority of the tubing is closer to the bottom end of the chamber and the modules than the top end. The tubing is in a helical pattern which extends upwardly from the inlet 60 to the outlet 62 as it is wound helically about the central axis. The fluid 58 is circulated in a closed loop from the outlet 62 through the hot source 12 and then to a pump 64 which pumps the fluid back into the inlet 62 for circulation through the inner chamber once again.

In the outer chamber the tubing circulates a second heat exchanging fluid 66 therethrough between the cold source 14 and the heat transfer medium 54 in the outer chamber. The second heat exchanging fluid in the outer chamber provides the function being a refrigerant or a coolant. The tubing in this instance is arranged in a helical pattern which extends through the outer chamber from an inlet portion 68 adjacent the top end of the chamber to an outlet portion 70 spaced downwardly from the inlet portion partway towards the bottom end of the chamber. The tubing in the outer chamber extends downwardly from the inlet to the outlet in a helical direction about the axis such that the majority of the tubing in the outer chamber is located in proximity to the top end of the chamber and the top end of the modules while being spaced upwardly from the bottom end of the chamber and modules therein. The second heat transfer fluid 66 is transferred in a closed loop from the outlet 70 to the cold source 14 and then to a suitable pump 72 which pumps the fluid from the source back to the inlet 68 for circulation to the outer chamber once again.

In the illustrated embodiment, a control device 74 is provided for operating the pumps 64 and 72 independently to circulate a sufficient amount of fluid through either of the chamber to maintain the first and second heat transfer mediums at ideal temperatures for efficient use of the generator modules. A suitable temperature sensor 76 is provided in associated with each closed loop of tubing so as to be in communication with the fluid in the heat transfer tubing exiting each chamber in proximity to the outlet 62 and 70 respectively or in communication with the first and second heat transfer mediums respectively for monitoring the temperature of the heat transfer mediums in contact with the modules. The control device 74 activates the pump associated with the first heat transfer fluid when the temperature recorded by the corresponding sensor 76 falls below a prescribed temperature threshold. Similarly the pump 72 associated with the second heat transfer fluid 66 is activated when the corresponding temperature sensor 76 indicates a temperature above a prescribed threshold of the cold loop.

In an alternative embodiment, the pumps 64 and 72 may be commonly driven in response to either temperature sensor 76 indicating that the respective temperature has crossed the respective threshold. This can be accomplished by provided two separate pumping modules that are driven together by a single motor to minimize power requirements.

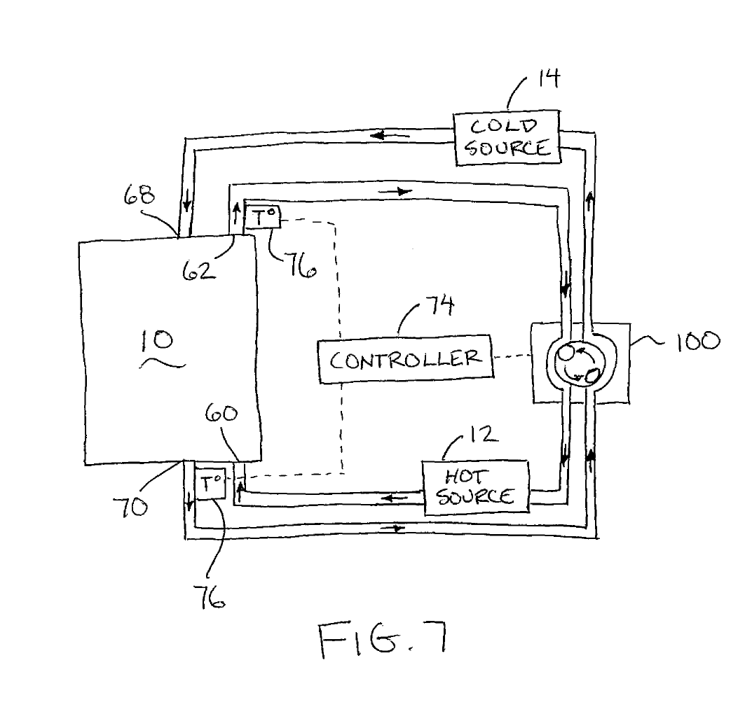

In yet a further embodiment as shown in FIG. 7, the pumps 64 and 72 may be replaced by a single pumping module 100, such as a peristaltic pump which is provided with two separated flow paths defined by respective tubing members receiving respective ones of the heat transfer fluids therethrough. In this instance, both tubing members pump fluid therethrough by engagement with a common rotor having a common set of rollers engaging the two tubing members.

In further embodiments, a conductive material may be used to form the exterior wall so that we may take advantage of outdoor ambient temperatures in colder climates for the cool side. A removable insulated shell or jacket that fits over the outside provides the option of either increased cooling when removed in colder climates or insulating to keep thing cold in hot climates.

As described herein, the device 10 is a transformer device which incorporates thermoelectric generators (TEGs) in a new configuration to produce electricity. Each TEG is a flat solid thin device consisting of 2 ceramic wafers with Semiconductors sandwiched between them. The TEG produces an electric current when heat is applied to the Hot Side (HS) of the Ceramic Surface and cold (C5) is applied to the other side of the wafer sandwich. There are a number of manufacturers of TEGs and they can operate at various temperatures. Two SEPARATE Heat Transfer Fluids (HTF) are used to supply and remove heat energy in 2 separate closed loop systems.

In this invention, 24 TEGs are wired together in series (or parallel depending on power requirements) to form a 6 sided pyramid like shape containing 4 TEGs per side and they are embedded in an insulated silicon rubber membrane. The designated hot side of the TEGs face/lean inwards and the designated cold side face outwards. The TEGs are positioned this way to allow the heat energy of the hot HTF to climb/rise and push on the inside surface (HS) of the TEGs and the colder HTF to slide/fall down and cool the outside cold surface of the TEGs.

The Hexagon Pyramid Shape (HPS) has the appearance of a 6 sided pyramid with the top cut off.

In further embodiments however, the shape of the device could change if the thermoelectric generator modules are flexible or are made to be curved instead of flat. In this instance the support wall, the inner wall and the outer wall can all be frusto-conical in shape.

The Insulated Membrane (IM) is thin and consists of woven fiberglass (for insulating) coated with High Temp Silicon Rubber. Other insulating materials such as silicon sponge and silicon impregnated with Aerogel may also function suitably. It keeps the HTFs separated during the process inside the Hexagon shape. Each TEG is sealed and imbedded in the membrane which prevents the 2 HTF systems from coming in contact with each other, and gives the appearance of TEGs imbedded in a wall like the windows in the walls of a house. This allows the ceramic surfaces of the TEGs to be directly ex-posed to the HTFs on both sides. The Cold side of the TEGs is directly exposed to the Cold HTF and the hot HTF to the Hot side.

The Membrane is sealed to, and situated in the middle of another insulated sealed Hexagon shape called the Membrane Tank (MemTank). The MemTank is slightly larger than the Membrane, hollow, and acts as a holding tank for the HTFs and heating/refrigeration elements. The insulated Membrane helps keep the Cold Side cold and the Hot Side hot. The MemTank is made of insulating Fiberglass Rollboard (or similar insulating material) coated and sealed with High Temp Silicon Rubber which prevents the HTFs from leaking out of the EC and insulates them from each other. Copper tubing is used to carry the HTFs and transfer energy from the 2 HTFs (heating and cooling). The HTF is used for both cooling and a heating. Two separate pumps move the Hot and Cold HTFs in 2 separate closed loop systems.

One copper tubing (cooling element) is coiled around the top of the outside the Membrane and spools downwards 4 times (4 rows) in the illustrated embodiment in the cold side of the MemTank. The 2nd Copper tubing (Heating element) is coiled around the bottom of the inside of the Membrane and spools upwards 4 times (4 rows) in the illustrated embodiment in the hot side of the MemTank.

In further embodiments, the tubing for the hot and cold sides may be coiled to span the full height of the respective chambers so that the tubing runs the entire length and width of the membrane on the hot and cold sides.

The 2 separate coils act as heating and cooling elements and carry the HTFs through the MemTank and they are separated by the membrane. Both hot side and cool side of the MemTank are filled with the same HTF. The refrigerant side in the closed loop system is cooled with a heat exchanger before it enters the MemTank and the other HTF is heated by any suitable hot source before it enters the MemTank.

As mentioned, thermodynamic convection plays an important roll in the EC allowing the Cold molecules of the HTF in the MemTank to fall/tumble down the (outside) cold face of the Membrane and the Hot molecules of the HTF to ascend the face (outside) of the Membrane.

The temperature of the heating element is controlled by a miniature temperature controller (MTC) and it tells the circulation pump to turn on. The MTC circuit also controls the circulation pump for the cooling element.

Since various modifications can be made in my invention as herein above described, and many apparently widely different embodiments of same made within the spirit and scope of the claims without department from such spirit and scope, it is intended that all matter contained in the accompanying specification shall be interpreted as illustrative only and not in a limiting sense.

1. A thermoelectric generator device for generating electrical power from a difference in temperature between a first source and a second source, the device comprising:
an inner wall which is generally annular about a central axis;
a support wall which is generally annular about the central axis so as to surround the inner wall at a location spaced radially outwardly from the inner wall to define an inner chamber which is annular in shape between the inner wall and the support wall;
an outer wall which is generally annular about the central axis so as to surround the support wall at a location spaced radially outwardly from the support wall to define an outer chamber which is annular in shape between the support wall and the outer wall;
a plurality of thermoelectric modules wherein:
each thermoelectric module comprises a first side, a second side, and a core between the first and second side which is arranged to generate electrical power when subjected to a temperature differential between its respective first and second sides; and
each thermoelectric module is supported on the support wall such that the first side is in communication with the inner chamber and such that the second side is in communication with the outer chamber;
a first heat transfer fluid in communication between the inner chamber and the first source; and
a second heat transfer fluid in communication between the outer chamber and the second source.

2. The device according to claim 1 wherein the support wall is polygonal so as to define a plurality of flat sides in series with one another in a circumferential direction about the central axis, each flat side supporting at least one thermoelectric module therein.

3. The device according to claim 2 wherein the inner wall is polygonal so as to define a plurality of flat sides in series with one another in a circumferential direction about the central axis, each flat side being parallel to a corresponding one of the flat sides of the support wall.

4. The device according to claim 2 wherein the outer wall is polygonal so as to define a plurality of flat sides in series with one another in a circumferential direction about the central axis, each flat side being parallel to a corresponding one of the flat sides of the support wall.

5. The device according to claim 1 wherein the support wall comprises heat insulating material and each module is supported in a respective aperture in the insulating material such that the module is in sealing engagement relative to the support wall about a perimeter of the thermoelectric module and such that the first side is in direct communication with the inner chamber and such that the second side is in direct communication with the outer chamber.

6. The device according to claim 1 wherein the inner wall comprises heat insulating material.

7. The device according to claim 1 wherein the outer wall comprises heat insulating material.

8. The device according to claim 1 wherein there is provided a first heat transfer medium in the inner chamber including tubing extending therethrough which receives the first heat transfer fluid therethrough.

9. The device according to claim 8 wherein the tubing extends through the first heat transfer medium in a helical pattern about the central axis.

10. The device according to claim 1 wherein there is provided a second heat transfer medium in the outer chamber including tubing extending therethrough which receives the second heat transfer fluid therethrough.

11. The device according to claim 10 wherein the tubing extends through the second heat transfer medium in a helical pattern about the central axis.

12. The device according to claim 1 further comprising:
a first heat transfer medium in the inner chamber including tubing extending therethrough from an inlet which receives the first heat transfer fluid from the first source to an outlet which returns the first heat transfer fluid to the first source; and
a second heat transfer medium in the outer chamber including tubing extending therethrough from an inlet which receives the second heat transfer fluid from the second source to an outlet which returns the second heat transfer fluid to the second source.

13. The device according to claim 12 wherein one or both of the heat transfer mediums comprises a liquid.

14. The device according to claim 12 wherein one or both of the heat transfer mediums comprises a conductive material.

15. The device according to claim 14 wherein one of the first and second sources comprises a hot source which is hotter than the other one of the first and second sources and wherein the tubing associated with the hot source extends upwardly through the respective heat transfer medium from the inlet to the outlet thereof.

16. The device according to claim 14 wherein one of the first and second sources comprises a cold source which is colder than the other one of the first and second sources and wherein the tubing associated with the cold source extends downwardly through the respective heat transfer medium from the inlet to the outlet thereof.

17. The device according to claim 1 wherein one of the first and second sides of each thermoelectric module comprises a hot side and the other one of the first and second sides of each thermoelectric module comprises a cold side arranged such that the core generates electrical power when the hot side is subjected to a temperature which is greater than the cold side, and wherein each thermoelectric module is supported at an inclination from vertical such that the hot side faces partially downward and such that the cold side faces partially upward.

18. The device according to claim 1 wherein the support wall is generally frustoconical in shape.

19. The device according to claim 1 further comprising:
a first heat transfer medium in the inner chamber including tubing extending therethrough from an inlet which receives the first heat transfer fluid from the first source to an outlet which returns the first heat transfer fluid to the first source; and
a second heat transfer medium in the outer chamber including tubing extending therethrough from an inlet which receives the second heat transfer fluid from the second source to an outlet which returns the second heat transfer fluid to the second source;
wherein the tubing associated with the hot side is located in the respective heat transfer medium nearer to a bottom end than a top end of the thermoelectric modules; and
wherein the tubing associated with the cold side is located in the respective heat transfer medium nearer to the top end than the bottom end of the thermoelectric modules.

20. A thermoelectric generator device for generating electrical power from a difference in temperature between a hot source and a cold source which is colder than the hot source, the device comprising:
a first boundary wall which is insulated;
a support wall supported parallel and spaced apart from the first boundary wall so as to define a first chamber between the first boundary wall and the support wall;
a second boundary wall which is insulated and which is supported parallel and spaced apart from the support wall opposite from the first boundary wall so as to define a second chamber between the support wall and the second boundary wall;
a plurality of thermoelectric modules wherein:
each thermoelectric module comprises a hot side, a cold side, and a core between the hot and cold sides which is arranged to generate electrical power when the hot side subjected to a temperature which is greater than the cold side; and
each thermoelectric module is supported on the support wall such that the hot side is in communication with the first chamber and such that the cold side is in communication with the second chamber;
a first heat transfer fluid in communication between the hot source and the first chamber adjacent a bottom side thereof; and
a second heat transfer fluid in communication between the cold source and the second chamber adjacent a top side thereof;
the support wall supporting each thermoelectric module at an inclination from vertical such that the hot side faces partially downward and such that the cold side faces partially upward.
